(19) United States
(12) Patent Application Publication
(10) Pub. No.: US 2020/0328350 A1
(43) Pub. Date: Oct. 15, 2020

(54) RESISTIVE RANDOM ACCESS MEMORY (RRAM) DEVICES EMPLOYING BOUNDED FILAMENT FORMATION REGIONS, AND RELATED METHODS OF FABRICATING

(71) Applicant: QUALCOMM Incorporated, San Diego, CA (US)

(72) Inventors: Bin Yang, San Diego, CA (US); Xia Li, San Diego, CA (US); Guoqing Chen, San Diego, CA (US)

(21) Appl. No.: 16/382,880

(22) Filed: Apr. 12, 2019

(51) Int. Cl. H01L 45/00; H01L 27/24

(52) U.S. Cl. CPC H01L 45/1273; H01L 27/2463; H01L 27/2436; H01L 45/08; H01L 45/1675; H01L 45/146; H01L 45/1608; H01L 45/165; H01L 45/1233

(57) ABSTRACT

An RRAM device is disclosed, having reduced area without increased performance variation, formed by employing a bounded filament formation region in which an oxide layer is thinner and an implanted ion concentration is higher than in a peripheral region of the oxide layer surrounding the bounded filament formation region. Filament formation is controlled to occur in a bounded region having a reduced area by thinning the oxide layer in the bounded region to increase an electric field strength in the bounded region. Defects in the bounded region are subject to greater force from the electric field than defects in the peripheral region. By implanting additional mobile ions or other ion species in the bounded region by an accurately controlled process, a higher concentration of defects is introduced into the bounded region to promote filament formation. Memory elements based on the RRAM device are formed at higher density and lower cost.

### BACKGROUND

### I. Field of the Disclosure

The technology of the disclosure relates generally to resistive random access memory (RRAM) devices, wherein the RRAM device can be employed in a memory bit cell in a memory system to store a memory state as an electrical resistance.

### II. Background

Integrated circuits (ICs) in computing devices read data from and write data to memory devices during normal operation. To determine the type of memory device(s) best suited for a particular device or application, several performance factors may be considered. Such factors include data access time, read/write cycling endurance, data retention duration, power consumption, operating voltage, density, and cost. Non-volatile memory (NVM) includes types of memory that are capable of storing data for a long period of time, even without power provided, but the time to read or write NVM may be longer than desired for storage that is frequently accessed by a processor.

Resistive random access memory (RAM) (RRAM) is a type of NVM that has become popular due to having significantly faster performance and lower energy utilization than other types of NVM. Thus, use of RRAM for NVM in a processor-based system may be more desirable in electronic devices, such as mobile devices, for example. RRAM stores a memory state as an electrical resistance having either a low-resistance state (LRS) or a high-resistance state (HRS) depending on an applied electric field. The LRS and the HRS are typically reliable, stable, and non-volatile. In conductive bridge RAM (CBRAM), the LRS is created by one or more filaments that may be formed at random locations in an oxide layer of an RRAM device structure depending on a first applied electric field. In the HRS, the filament is dispersed by a second electric field.

### SUMMARY OF THE DISCLOSURE

Aspects disclosed herein include resistive random access memory (RRAM) devices employing bounded filament formation regions. Related fabrication methods are also disclosed. RRAM devices may be employed in memory bit cells in a memory array that maintains memory states representing binary data to provide memory for a processor-based system. The memory states of an RRAM device are defined by stable, non-volatile states of electrical resistance, which include a low-resistance state (LRS) and a high-resistance state (HRS). The LRS and HRS are determined by the presence or absence of a filament, which is a low resistance conductive path consisting of a chain of mobile defects or vacancies caused by mobile ions in an oxide layer. Filaments may be reversibly formed and dispersed in response to an applied electric field. However, the mobile defects drift in an unpredictable manner in response to the electric field, so the location and electrical resistance of filaments formed by clusters of defects cannot be reliably predicted. Performance variation among RRAM devices increases as an area of the oxide layers of such devices is reduced. Consequently, RRAM device performance becomes more unreliable as device sizes are scaled down.

To scale down an RRAM device size without sacrificing performance reliability, exemplary aspects disclosed herein provide an RRAM device employing a bounded filament formation region (“bounded region”) including a thin oxide layer. The thin oxide layer has a greater concentration of defects than in a peripheral region of the oxide layer, surrounding the bounded region, to allow a reduction in area without increasing performance variability. Formation of a filament in the oxide layer is focused in the bounded region by thinning the oxide layer to increase an electric field strength applied therein in comparison to a peripheral region in which the oxide layer is thicker and a voltage differential is the same. As a result, the defects in the bounded region are subject to greater electric field forces than defects in the peripheral region, which increases a chance of defect migration and clustering. In addition, by implanting mobile ions in the bounded region using an accurately controlled process, a higher concentration of defects may occur in the bounded region, which makes filament formation more likely to occur in the bounded region than in the peripheral region. By controlling oxide layer thickness and ion concentration in a bounded region, filament formation may be reliably focused in the bounded region, so an area of a peripheral region of the oxide layer may be reduced. In this regard, an RRAM device as disclosed herein may be scaled down to a smaller area than a conventional RRAM device without increasing device performance variability. Thus, memory elements based on the RRAM device as disclosed herein may also be formed with higher density and lower cost.

In this regard, in one aspect, an RRAM device is disclosed. The RRAM device includes a bottom electrode including a top surface. The RRAM device also includes an oxide layer disposed on the top surface of the bottom electrode. The oxide layer includes a bounded region having a first thickness above the top surface of the bottom electrode. The oxide layer also includes a peripheral region surrounding the bounded region and having a second thickness above the top surface of the bottom electrode greater than the first thickness. The RRAM device also includes a top electrode. The top electrode includes a first electrode structure disposed on the oxide layer in the peripheral region. The top electrode also includes a second electrode structure disposed on the oxide layer in the bounded region and above the first electrode structure over the bounded region. The RRAM device also includes a spacer disposed around the second electrode structure of the top electrode and above the first electrode structure of the top electrode.

In another aspect, a method of fabricating an RRAM device is disclosed. The method includes forming a bottom electrode. The method also includes forming an oxide layer having a second thickness above the bottom electrode. The oxide layer includes a bounded region and a peripheral region surrounding the bounded region. The method also includes forming a first electrode structure of a top electrode on the bounded region of the oxide layer and on the peripheral region of the oxide layer surrounding the bounded region. The method also includes forming a spacer on the first electrode structure above the peripheral region of the oxide layer surrounding the bounded region. The method also includes removing a portion of the first electrode structure of the top electrode above the bounded region of the oxide layer. The method also includes thinning the bounded region of the oxide layer to a first thickness. The method also includes forming a second electrode structure of the top electrode on the bounded region of the oxide layer extending above the first electrode structure of the top electrode and surrounded by the spacer.

In another aspect, a memory array including one or more RRAM bit cell circuits is disclosed. The one or more RRAM bit cell circuits each include a resistive RRAM device, including a bottom electrode, an oxide layer disposed over the bottom electrode, a top electrode, and a spacer. The oxide layer includes a bounded region having a first thickness, and a peripheral region surrounding the bounded region and having a second thickness greater than the first thickness. The top electrode of the RRAM device in the memory array is configured to receive a bit line voltage V_{BL} on a bit line, and the top electrode includes a first electrode structure disposed on the oxide layer in the peripheral region and a second electrode structure extending below the first electrode structure and disposed on the oxide layer in the bounded region. The spacer is disposed around the second electrode structure of the top electrode and above the first electrode structure of the top electrode. The RRAM bit cell circuit also includes an access transistor configured to couple a first source line voltage to the bottom electrode of the RRAM device in response to a gate voltage received on a word line. The oxide layer in the RRAM device in the array is configured to reversibly switch between a LRS and a HRS in response to a first voltage differential between the top electrode and the bottom electrode.

### BRIEF DESCRIPTION OF THE FIGURES

FIGS. 1A and 1C are a top cross-sectional view of an oxide layer with dispersed defects and a side cross-sectional view of the oxide layer with a chain of defects forming a filament, respectively, in a conventional resistive random access memory (RRAM) device illustrated in FIG. 1B.

FIG. 2A is a cross-sectional side view of an RRAM device as a discrete component employing a bounded filament formation region (“bounded region”) including a thin oxide layer having a greater concentration of defects than in a peripheral region of the oxide layer to reduce RRAM device area without increasing performance variability, including defects in the bounded region forming a filament;

FIG. 2B is a cross-sectional top view of the oxide layer in the RRAM device in FIG. 2A employing a bounded region including a thin oxide layer having a greater concentration of defects than in a peripheral region of the oxide layer;

FIG. 3 is a cross-sectional side view of an RRAM device employing a bounded region including a thin oxide layer having a greater concentration of defects than in a peripheral region of the oxide layer, and fabricated according to a complementary metal-oxide semiconductor (CMOS) self-aligned fabrication process disclosed herein;

FIG. 4 is a flowchart illustrating an exemplary process for fabricating the RRAM device 300A in FIG. 3 employing a bounded region including a thin oxide layer having a greater concentration of defects than in a peripheral region of the oxide layer;

FIGS. 5A-5S illustrate exemplary fabrication stages of fabricating an exemplary RRAM device employing a bounded region including a thin oxide layer having a greater concentration of defects than in a peripheral region of the oxide layer to reduce area without increasing performance variability;

FIG. 6 is a schematic diagram of an RRAM bit cell circuit comprising an RRAM device, such as the RRAM device in FIGS. 2A and 3, coupled to an access transistor through which a voltage can be applied to set or reset the RRAM device to store data;

FIG. 7 is a schematic diagram of an exemplary RRAM array comprising a plurality of RRAM bit cell circuits such as the RRAM bit cell circuit of FIG. 6 organized in rows and columns, each including the RRAM device of FIG. 3;

FIG. 8 is a block diagram of an exemplary processor-based system that can include an RRAM device employing a bounded region including a thin oxide layer having a greater concentration of defects than in a peripheral region of the oxide layer, including, but not limited, to the RRAM devices in FIGS. 2A, 3, and 5S; and

FIG. 9 is a block diagram of an exemplary wireless communications device that includes radio frequency (RF) components formed from an integrated circuit (IC), wherein any of the components therein can include an RRAM device employing a bounded region including a thin oxide layer having a greater concentration of defects than in a peripheral region of the oxide layer including, but not limited, to the RRAM devices in FIGS. 2A, 3, and 5S, the RRAM bit cell circuit in FIG. 6, and the RRAM array in FIG. 7.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed herein include resistive random access memory (RRAM) devices employing bounded filament formation regions. Related fabrication methods are also disclosed. RRAM devices may be employed in memory bit cells in a memory array that maintains memory states representing binary data to provide memory for a processor-based system. The memory states of an RRAM device are defined by stable, non-volatile states of electrical resistance, which include a low-resistance state (LRS) and a high-resistance state (HRS). The LRS and HRS are determined by the presence or absence of a filament, which is a low resistance conductive path consisting of a chain of mobile defects or vacancies caused by mobile ions in an oxide layer. Filaments may be reversibly formed and dispersed in response to an applied electric field. However, the mobile defects drift in an unpredictable manner in response to the electric field, so the location and electrical resistance of filaments formed by clusters of defects cannot be reliably predicted. Performance variation among RRAM devices increases as an area of the oxide layers of such devices is reduced. Consequently, RRAM device performance becomes more unreliable as device sizes are scaled down.

To scale down an RRAM device size without sacrificing performance reliability, exemplary aspects disclosed herein provide an RRAM device employing a bounded filament formation region (“bounded region”) including a thin oxide layer. The thin oxide layer has a greater concentration of defects than in a peripheral region of the oxide layer, surrounding the bounded region, to allow a reduction in area without increasing performance variability. Formation of a filament in the oxide layer is focused in the bounded region by thinning the oxide layer to increase an electric field strength applied therein in comparison to a peripheral region in which the oxide layer is thicker and a voltage differential is the same. As a result, the defects in the bounded region are subject to greater electric field forces than defects in the peripheral region, which increases a chance of defect migration and clustering. In addition, by implanting mobile ions in the bounded region using an accurately controlled process, a higher concentration of defects may occur in the bounded region, which makes filament formation more likely to occur in the bounded region than in the peripheral region. By controlling oxide layer thickness and ion concentration in a bounded region, filament formation may be reliably focused in the bounded region, so an area of a peripheral region of the oxide layer may be reduced. In this regard, an RRAM device as disclosed herein may be scaled down to a smaller area than a conventional RRAM device without increasing device performance variability. Thus, memory elements based on the RRAM device as disclosed herein may also be formed with higher density and lower cost.

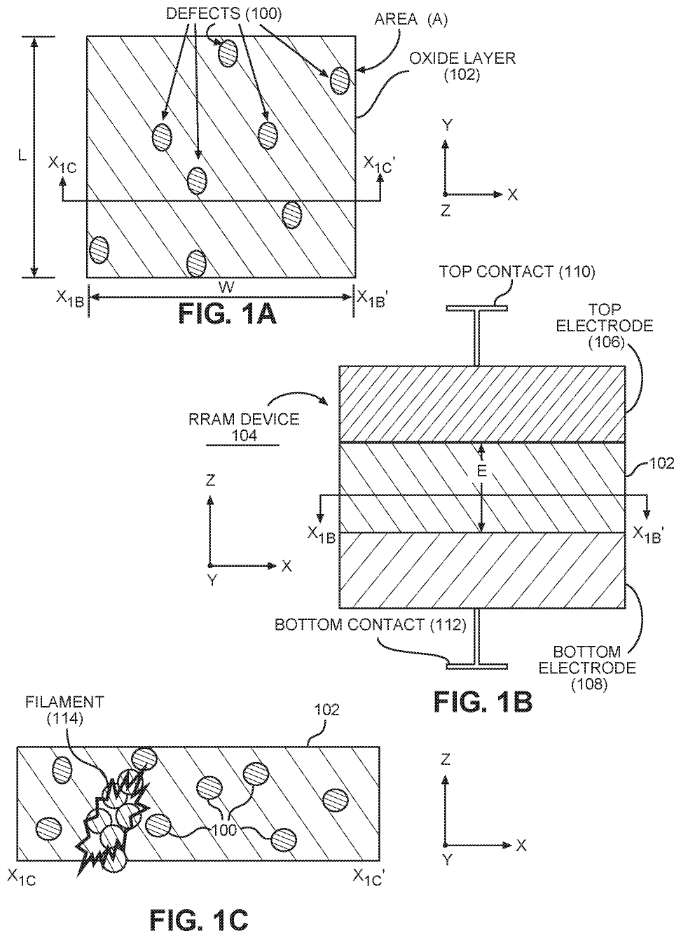

FIG. 1A is a top view of defects 100 randomly dispersed over the horizontal (X-axis and Y-axis directions) area A=L×W of an oxide layer 102 with a length L and width W in an RRAM device 104, shown in FIG. 1B. FIG. 1A is a cross-sectional view in the Z-axis direction taken at line X_{1B}-X_{1B}′ of the oxide layer 102. The defects 100 are created by mobile ions in the oxide layer 102. For example, the defects 100 may be created by mobile oxygen ions (O²⁻) or other types of mobile ions in the oxide layer 102. Mobile ions are incorporated into the oxide layer 102 due to the presence of impurities in the atmosphere of a fabrication chamber. In this way, the mobile ions are included at random locations in the structure of the oxide layer 102 as it is grown. The defects 100 created by the mobile ions are charged and are capable of migrating under the influence of an electric field E. The electric field E may be applied to the RRAM device 104 by a voltage difference (referred to herein as a voltage differential) between a top electrode 106 and a bottom electrode 108. The voltage differential is applied between a top contact 110 coupled to the top electrode 106 and a bottom contact 112 coupled to the bottom electrode 108. The voltage differential creates the electric field E between the top electrode 106 and the bottom electrode 108 in the thickness direction (Z-axis direction) of the oxide layer 102. In response to a first electric field applied to the oxide layer 102, defects 100 in the oxide layer 102 can migrate and eventually create a conductive chain of defects 100 in the thickness direction (Z-axis direction) of the oxide layer 102, as shown in the cross-sectional view in FIG. 1C taken at line X_{1C}-X_{1C}′ in FIG. 1A. This conductive chain of defects 100 creates a low-resistance path known as a filament 114 through the oxide layer 102. Thus, the first electric field V_{SET} can “set” the RRAM device 104 into a low-resistance state (LRS) by creating a filament 114. A second electric field V_{RESET}, which may be of a different magnitude and/or polarity than the first electric field V_{SET}, can “reset” the RRAM device 104 to a high-resistance state (HRS) by dispersing the conductive chain of defects 100 that formed the filament 114. However, the location in which a filament 114 is formed in the area A in response to the first applied electric field is unpredictable, and this can also affect the electrical resistance of the filament 114. Randomness in the formation of filaments causes performance variability of an RRAM device, such as the RRAM device 104. Since defects 100 may be distributed randomly in an oxide layer 102, a number of defects 100 is more predictable in a larger area A than in a smaller area. Therefore, an increase in size of the RRAM device 104 can provide more consistent performance, and scaling down the area A may reduce a performance reliability of the RRAM device 104.

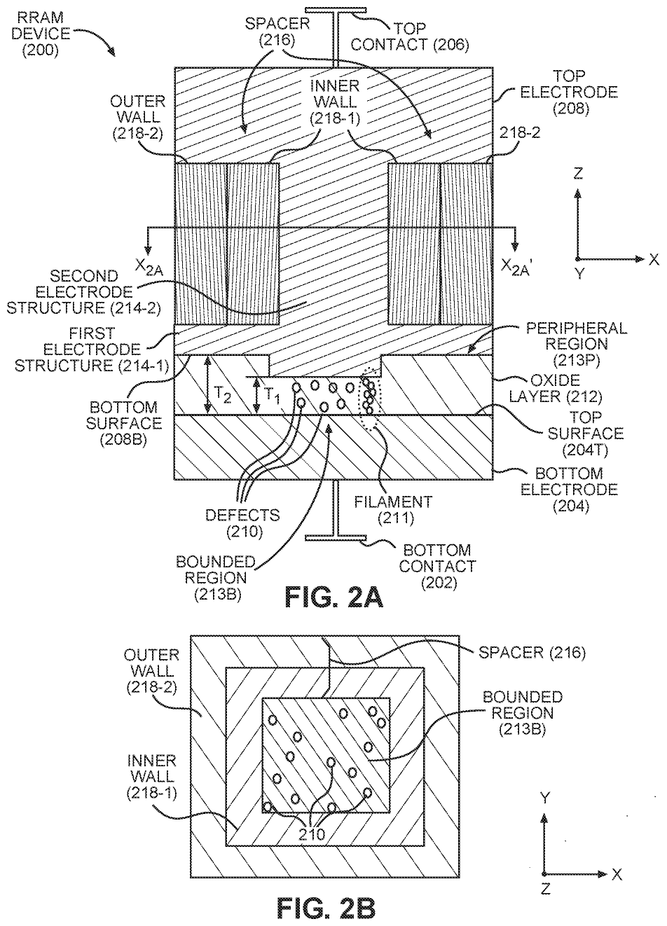

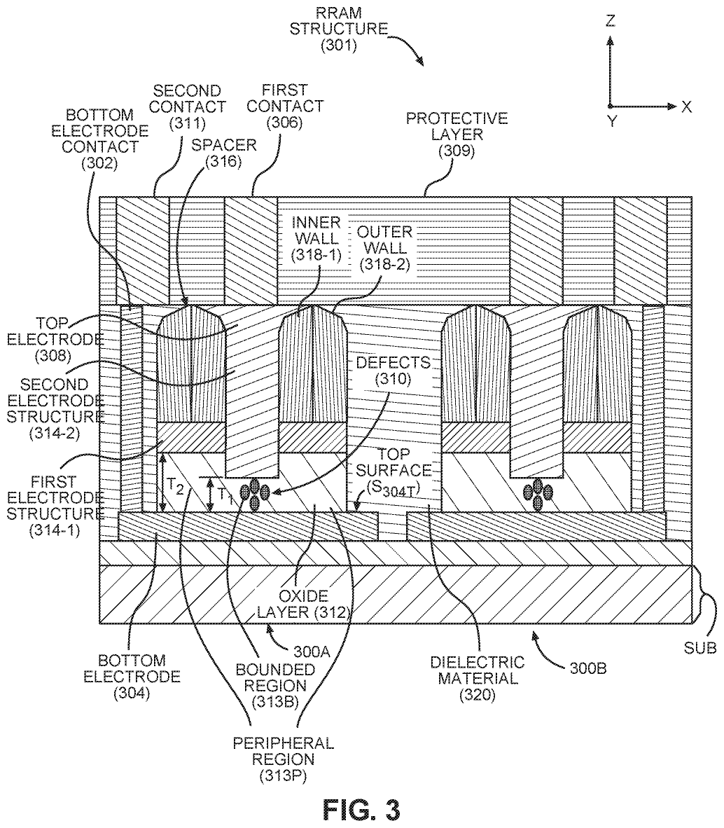

FIG. 2A is a cross-sectional side view of an exemplary RRAM device 200 that can be used to form a bit cell in a RRAM memory. As discussed in more detail below, the RRAM device 200 employs a bounded region 213B in which the oxide layer 212 is thinner and has a greater concentration of defects 210 than in a peripheral region 213P of the oxide layer 212. Formation of a filament 211 in the oxide layer 212 is focused in the bounded region 213B by thinning the oxide layer 212 to increase an electric field strength applied therein with respect to a peripheral region 213P in which the oxide layer 212 is thicker and an applied voltage differential is the same. As a result, the defects 210 in the bounded region 213B are subject to greater electric field forces than defects 210 in the peripheral region 213P, which increases a chance of defect migration and clustering. The entire oxide layer 212, including the peripheral region 213P and the bounded region 213B, includes randomly dispersed defects 210 that were created in the oxide layer 212 during fabrication, as explained above. However, by implanting mobile ions in the bounded region using an accurately controlled process, a higher concentration of defects 210 may occur in the bounded region 213B, which advantageously makes filament formation more likely to occur in the bounded region 213B than in the peripheral region 213P. The concentration of defects 210 in the bounded region 213B due to implanted mobile ions may be, for example, at least twice the concentration of defects 210 in the peripheral region 213P. The mobile ions may be implanted with implantation energy in the range of 5 Kilo electron Volts (KeV) to 200 KeV and a dose resulting in a defect concentration due to implanted mobile ions of 10E11/cm² to 10E14/cm² in the bounded region 213B. The memory states of the RRAM device 200 are defined by a low-resistance state (LRS) and a high-resistance state (HRS) determined by the presence or absence of a filament. Increasing a probability that filaments will be reliably formed in the bounded region 212B, and not in the peripheral region 213P, allows the area of the peripheral region 213P to be reduced, so the RRAM device 200 can be scaled down, while still achieving reliable performance. In FIGS. 2A and 2B, as well as FIGS. 3, 5A-5S, and 6, below, a higher density of the defects 210, 310 is emphasized by illustrating the defects 210, 310 where they are intentionally implanted by the controlled process (e.g., the bounded region 212B, 313B), and not where the defects 210, 310 may be randomly dispersed during fabrication.

The voltage is applied to the RRAM device 200 through a bottom contact 202 and a top contact 206. The bottom contact 202 is coupled to a bottom electrode 204, and the top contact 206 is coupled to a top electrode 208. The oxide layer 212 is disposed in an area between the top electrode 208 and the bottom electrode 204, and the applied voltage provided to the top and bottom electrodes 208 and 204 creates the electric field in that area in which the oxide layer 212 is disposed. The RRAM device 200 can be set into the LRS by applying a first voltage V_{SET} between the bottom contact 202 and the top contact 206. In response to the applied voltage, an electric field is created between a top surface 204T of the bottom electrode 204 and a bottom surface 208B of the top electrode 208 in the oxide layer 212.

The oxide layer 212 is thinned in the bounded region 213B to increase the electric field in comparison to the electric field in the peripheral region 213P of the oxide layer 212. The peripheral region 213P fully surrounds the bounded region 213B, providing a continuous, unbroken boundary around an entire perimeter of the bounded region 213B to avoid any edge effects and maintain uniformity within the bounded region 213B. A first thickness T1 between the top surface 204T of the bottom electrode 204 and the bottom surface 208B of the top electrode 208 in the bounded region 213B is based on a first thickness T1 of the oxide layer 212 above the top surface 204T of the bottom electrode 204. The peripheral region 213P of the oxide layer 212 having a second thickness T2 surrounds the bounded region 213B and has a greater thickness than the bounded region 213B. As explained below, the oxide layer 212 is first formed in the second thickness T2 and then thinned to the first thickness T1 in the bounded region 213B. The oxide layer 212 is deposited in the second thickness T2 having a range of two (2) nm to twenty (20) nm. The first thickness T1 of the oxide layer 212 in the bounded region 213B is less than the second thickness T2 in the peripheral region 213P by a range of one (1) nm to ten (10) nm. In this regard, the first thickness T1 of the oxide layer 212 in the bounded region 213B may be in the range of 50% to 90% of the second thickness T2 in the peripheral region 213P.

Since the first thickness T1 between the top electrode 208 and the top surface 204T of the bottom electrode 204 in the bounded region 213B of the oxide layer 212 is smaller than the second thickness T2 in the peripheral region 213P, an electric field in the oxide layer 212 due to the first voltage V_{SET} is stronger in the bounded region 213B than in the peripheral region 213P. A stronger electric field in the bounded region 213B exerts a stronger force on defects 210 in the oxide layer 212 in the bounded region 213B than in the peripheral region 213P. Consequently, the probability of formation of a filament 211 through the oxide layer 212 in the bounded region 213B (i.e., the thinner area of the oxide layer 212) in response to the first voltage V_{SET} is much higher than in thicker area of the peripheral region 213P. Reliable formation of a filament 211 in the bounded region 213B allows the area of the peripheral region 213P to be reduced so the RRAM device 200 can be scaled down, while still achieving reliable performance.

In another aspect, the probability of formation of a filament in response to the first voltage V_{SET} may also be increased in the bounded region 213B compared to the peripheral region 213P by a higher concentration of the defects 210 in the bounded region 213B than in the peripheral region 213P. To achieve a higher concentration of defects 210 in the bounded region 213B, mobile ions are implanted into the bounded region 213B during fabrication, as explained in more detail below. The implanted mobile ions may be oxygen ions and other species of ions, such as hafnium (Hf), tantalum (Ta), titanium (Ti), and manganese (Mn), for example. The ions are provided to intentionally create a higher concentration of the filament-forming defects 210 in the oxide layer 212 to further increase a probability of formation of filaments 211 in the bounded region 213B compared to the peripheral region 213P.

With continued reference to FIG. 2A, the top surface 204T of the bottom electrode 204 may be a planar top surface, and the oxide layer 212 may be formed on the planar top surface 204T. Thus, to form the bounded region 213B in which the oxide layer 212 has the thinner second thickness T2, the oxide layer 212 is formed having the first thickness T1, as in the peripheral region 213P, and the oxide layer 212 is thinned from above by etching the bounded region 213B, as explained below. The top electrode 208 includes a first electrode structure 214-1 disposed on the oxide layer 212 in the peripheral region 213P. The top electrode 208 also includes a second electrode structure 214-2 disposed on the oxide layer 212 in the bounded region 213B and extending above the first electrode structure 214-1 over the bounded region 213B. The RRAM device 200 also includes a spacer 216 disposed around a perimeter of the second electrode structure 214-2 and above the first electrode structure 214-1 of the top electrode 208. The second electrode structure 214-2 may have a cross-section along line X_{2A}-X_{2A}′ in the X-axis and Y-axis directions in FIG. 2A, as shown in FIG. 2B. An axis of the second electrode structure 214-2 extends along an axis in a first direction that is orthogonal to a plane of the first electrode structure 214-1. In the example in FIG. 2B, the bounded region 213B may be of any desired shape. The spacer 216 includes an inner wall 218-1 adjacent to a perimeter of the second electrode structure 214-2 and surrounding the second electrode structure 214-2. Thus, the inner wall 218-1 may be a closed wall, meaning that the inner wall 218-1 forms an unbroken boundary in the shape of, for example, a square shape, a rectangle shape, a circular shape, or other shape around the second electrode structure 214-2. In this regard, the inner wall 218-1 surrounds an area directly above and coinciding in shape with an area of the bounded region 213B. The spacer 216 also includes an outer wall 218-2 that is outside and adjacent to the inner wall 218-1. As shown in FIG. 2A, the spacer 216 is disposed above the peripheral region 213P of the oxide layer 212.

FIG. 3 is a cross-sectional side view of RRAM devices 300A and 300B in an RRAM structure 301 formed on a substrate SUB by a complementary metal-oxide semiconductor (CMOS)-compatible process described below. The RRAM devices 300A and 300B are each functionally equivalent to the RRAM device 200 in FIG. 2A and include the same or similar structural aspects of the oxide layer 212, the top electrode 208, and spacer 216. Using the RRAM device 300A as an example, a bottom electrode contact 302 is coupled to a top surface S_{304T} of bottom electrode 304. Like the RRAM device 200, the RRAM device 300A includes a first contact 306 coupled to a top electrode 308 through a protective layer 309 and a second contact 311 coupled to the bottom electrode contact 302. Thus, the first voltage V_{SET} may be applied across the first contact 306 and the second contact 311 from the same side of the RRAM devices 300A and 300B. The RRAM devices 300A and 300B in FIG. 3 are electrically separate and symmetric to each other, having opposite but otherwise identical structural features to reduce routing in a memory circuit in which the RRAM devices 300A and 300B may be included (not shown). Since the RRAM devices 300A and 300B are structurally equal to each other, a description of only RRAM device 300A is provided to avoid redundancy.

A bounded region 313B of an oxide layer 312 has a first thickness T1 above the bottom electrode 304, which is less than a second thickness T2 of the oxide layer 312 in a peripheral region 313P that surrounds the bounded region 313B. Therefore, as discussed above, a distance between a second electrode structure 314-2 of the top electrode 308 and the top surface S_{304T} of the bottom electrode 304 in the bounded region 313B is less than a distance between a first electrode structure 314-1 of the top electrode 308 and the top surface S_{304T} of the bottom electrode 304 in the peripheral region 313P. In this regard, a probability of formation of a filament through the oxide layer 312 in response to the first voltage V_{SET} is higher in the thinner area of the bounded region 313B than in the peripheral region 313P. The probability of formation of a filament in the bounded region 313B in response to the first voltage V_{SET} is further increased with respect to the peripheral region 313P by a higher concentration of ions implanted in the bounded region 313B to provide a higher concentration of filament-forming defects 310 in the oxide layer 312. By increasing a probability of filament formation in the bounded region 313B with respect to the peripheral region 313P, filament formation will more reliably occur in the bounded region 313B. With filament formation reliably occurring in the bounded region 313B, an area of the peripheral region 313P of the oxide layer 312 can be reduced without reducing reliability of the RRAM device 300A. In this regard, the RRAM devices 300A and 300B in FIG. 3 can be scaled down to enable higher density memory without a loss of reliability.

With further reference to FIG. 3, the RRAM device 300A includes a spacer 316 disposed around the second electrode structure 314-2 and above the first electrode structure 314-1 of the top electrode 308. The spacer 316 is employed to determine a cross-sectional area of the bounded region 313B in the fabrication process described below and also to determine the corresponding cross-sectional area of the second electrode structure 314-2, which is smaller than an area of the first electrode structure 314-1. The spacer 316 includes an inner wall 318-1 adjacent to and surrounding the second electrode structure 314-2. Thus, the inner wall 318-2 may be a closed wall, meaning that the inner wall 318-2 forms a continuous boundary in the shape of, for example, a square shape, a rectangular shape, a circular shape, or other shape according to the desired shape of the bounded region 213B and the second electrode structure 314-2. In this regard, the inner wall 318-1 surrounds an area directly above and coinciding in shape with an area of the bounded region 313B. The spacer 316 also includes an outer wall 318-2 that is outside and adjacent to the inner wall 318-1. As shown, the spacer 316 is disposed above the peripheral region 313P of the oxide layer 312 and is separated from the oxide layer 312 by the thickness of the first electrode structure 314-1. In the RRAM structure 301 shown in FIG. 3, the RRAM devices 300A and 300B are enclosed in dielectric material 320 for electrical isolation from each other and to avoid shorts.

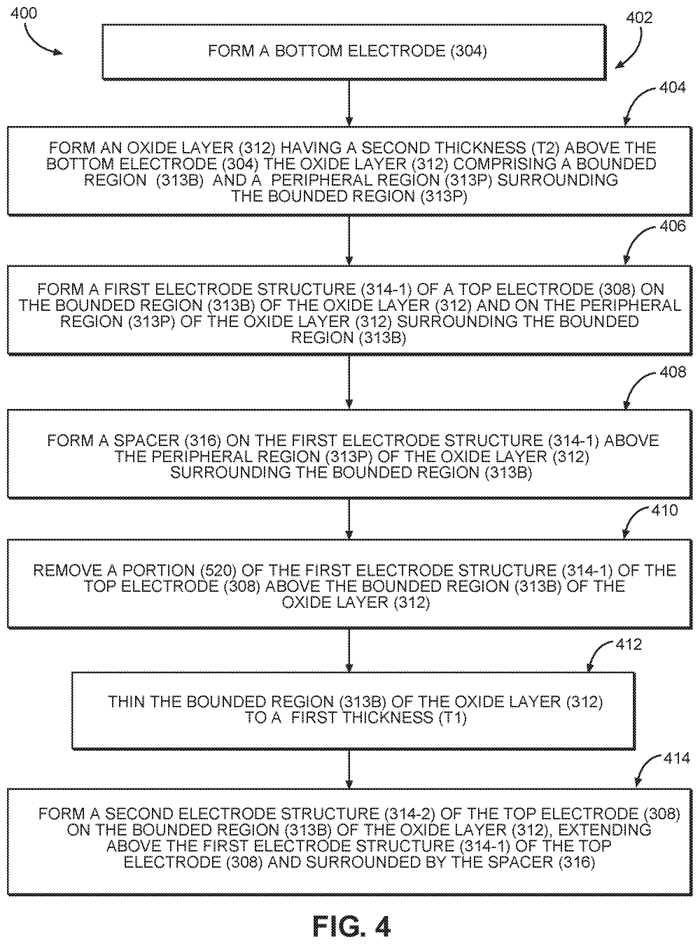

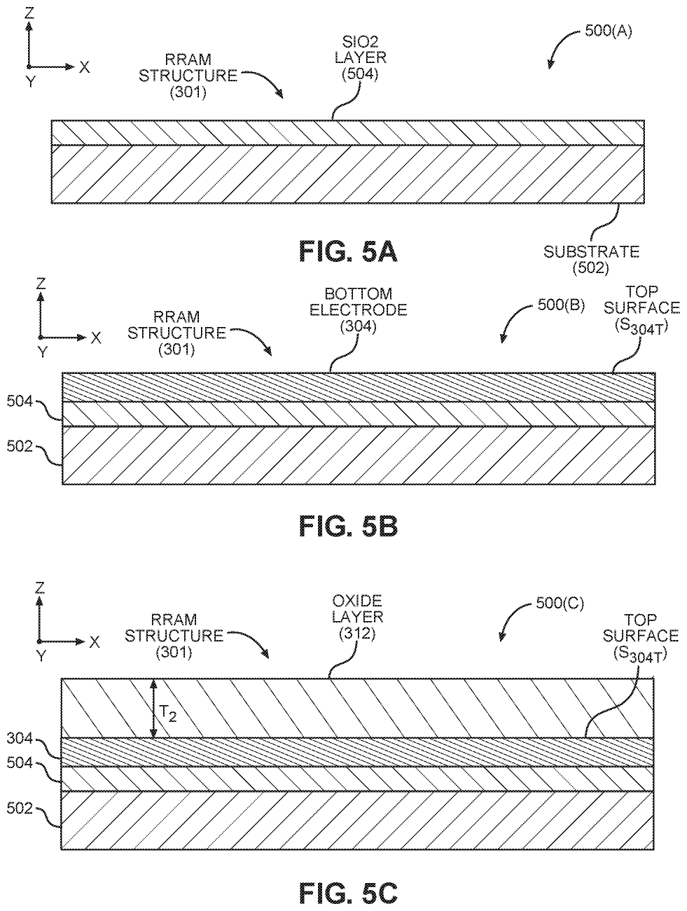

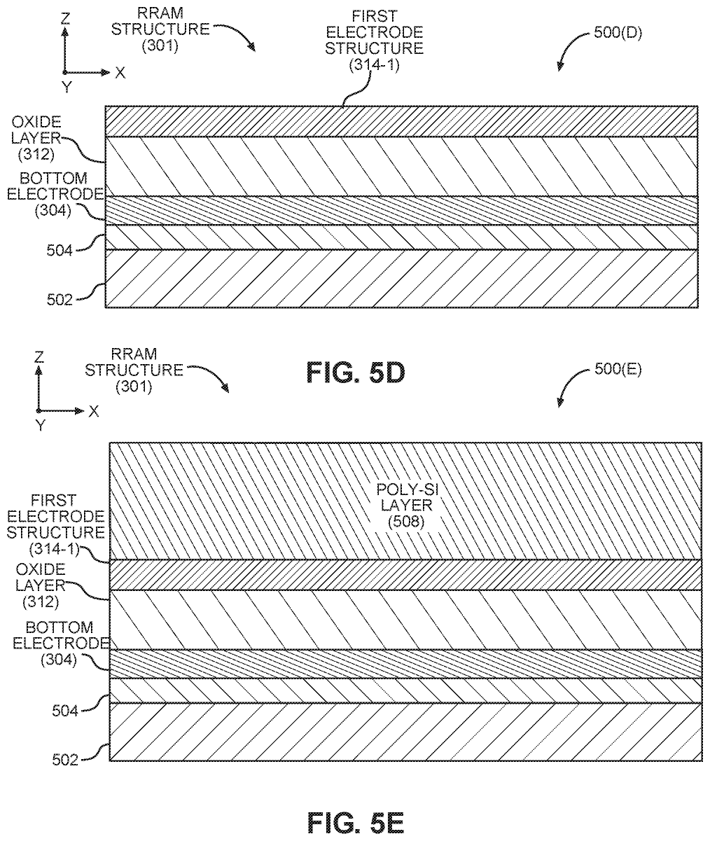

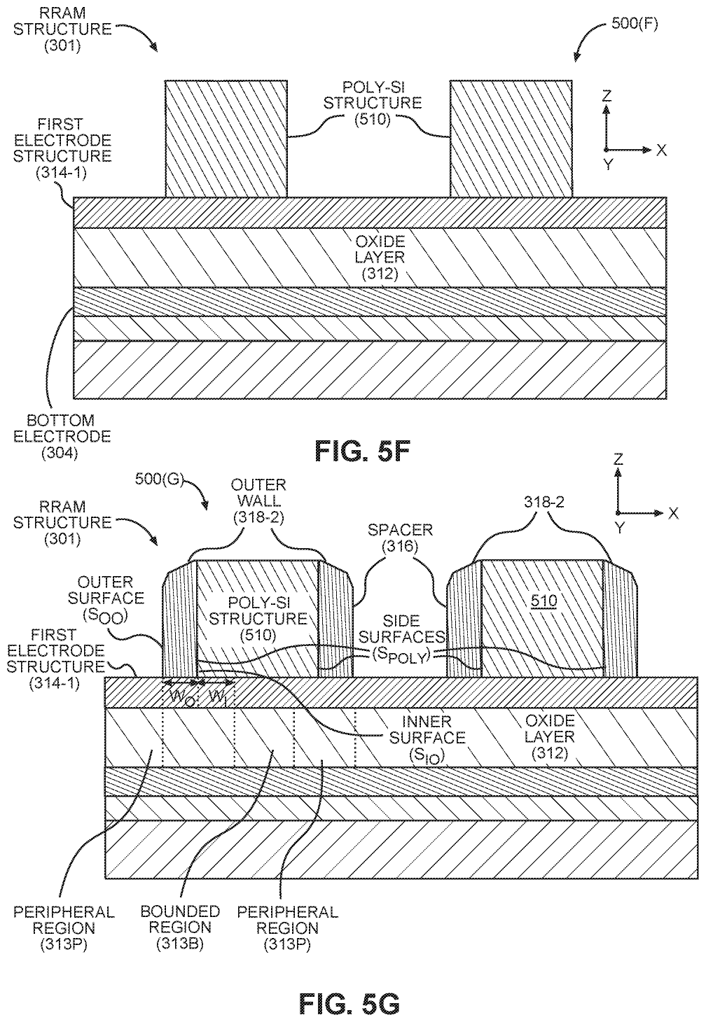

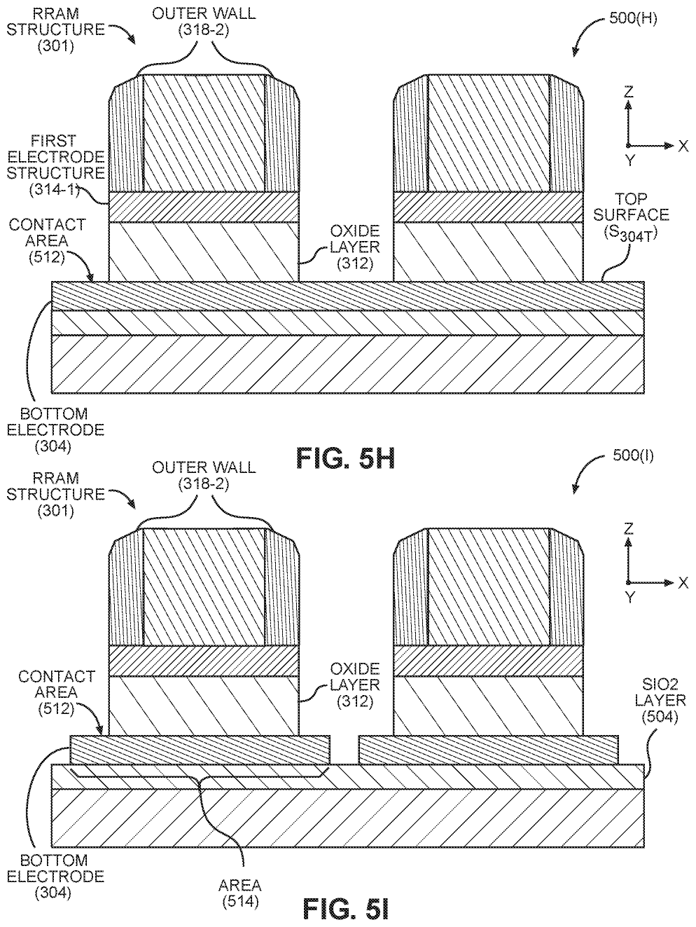

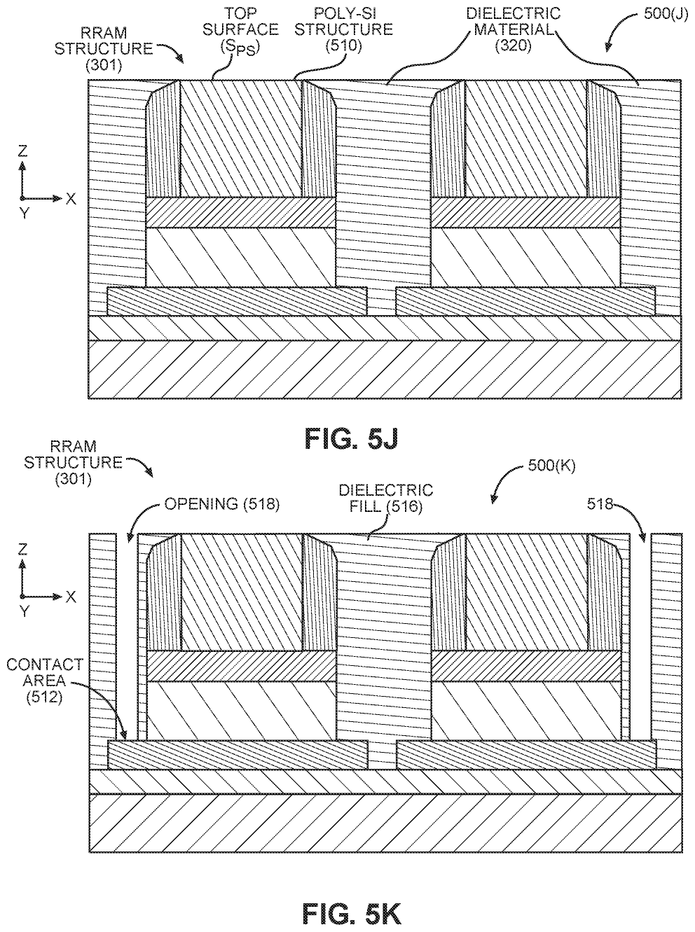

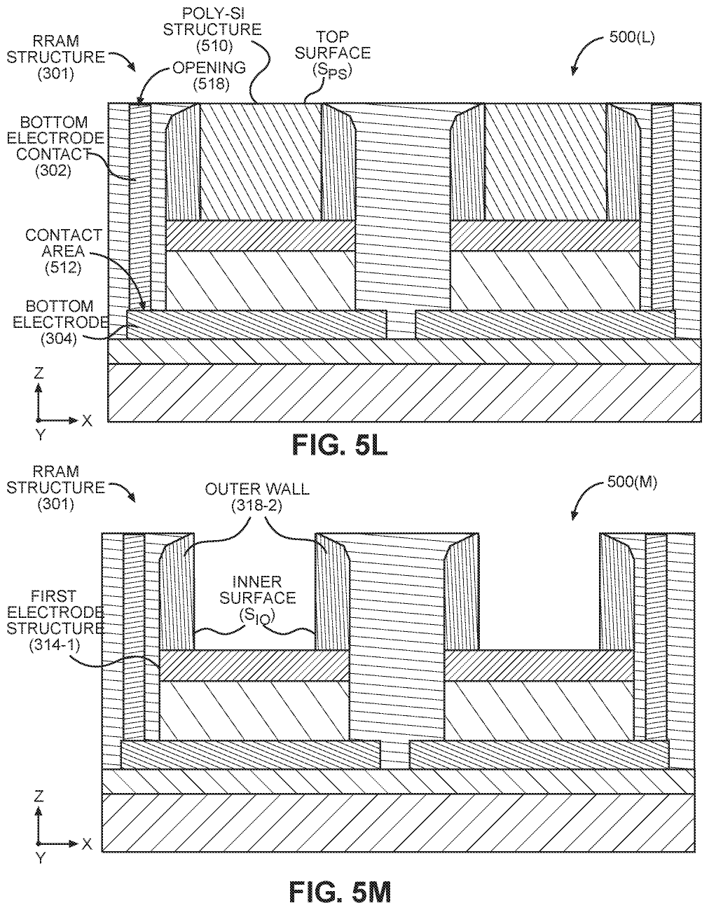

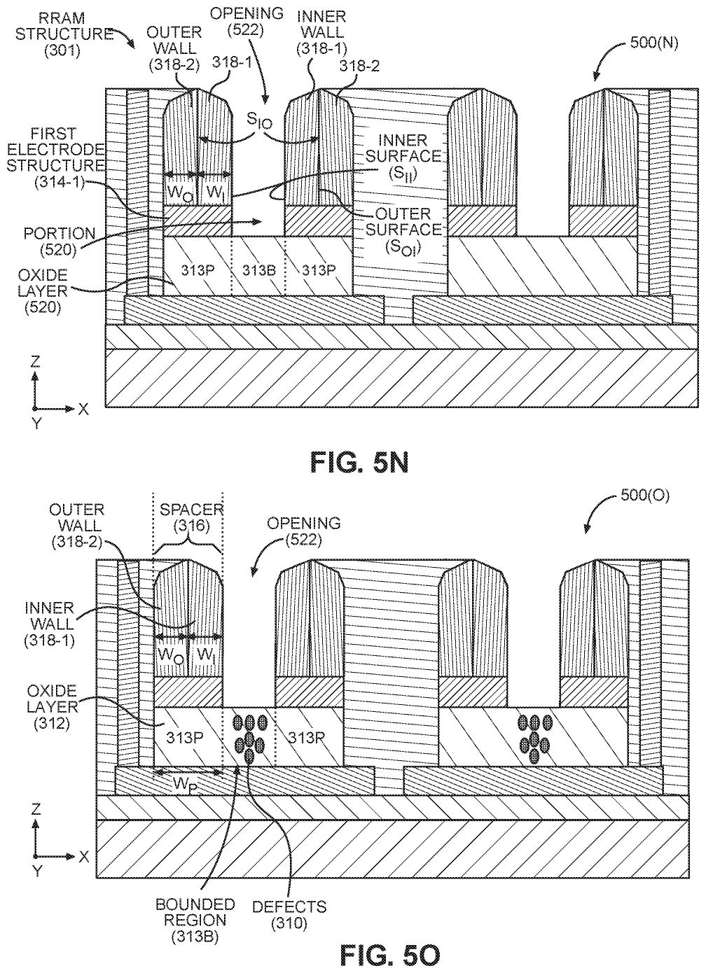

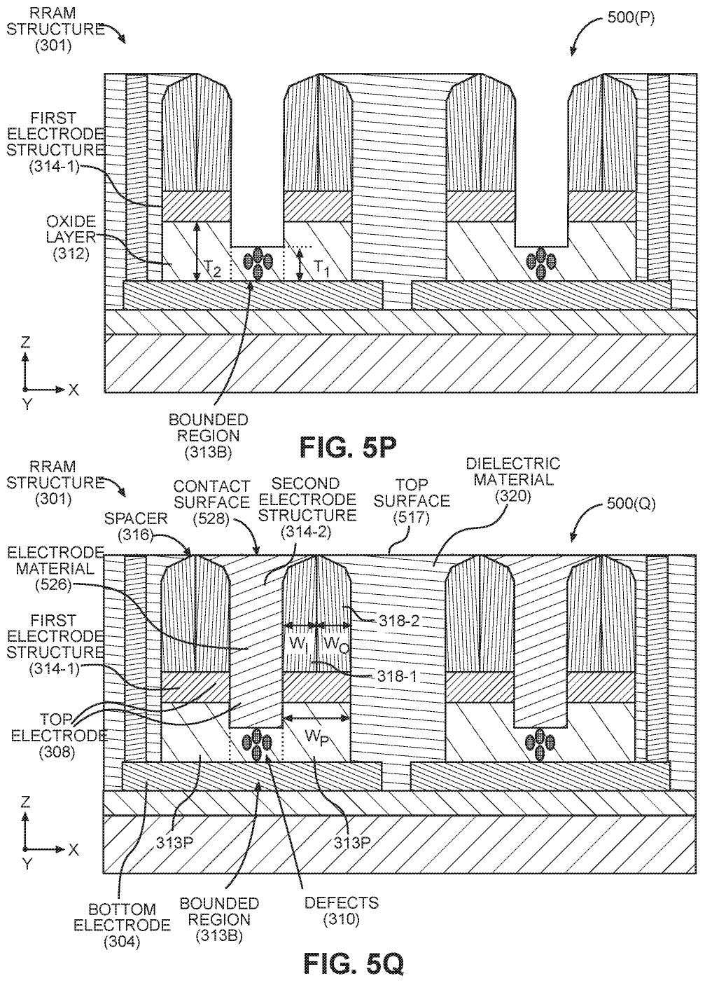

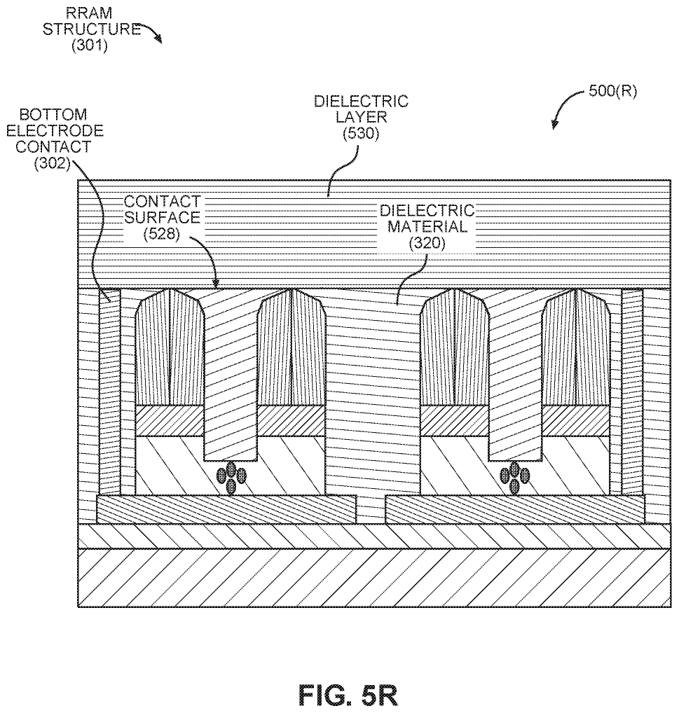

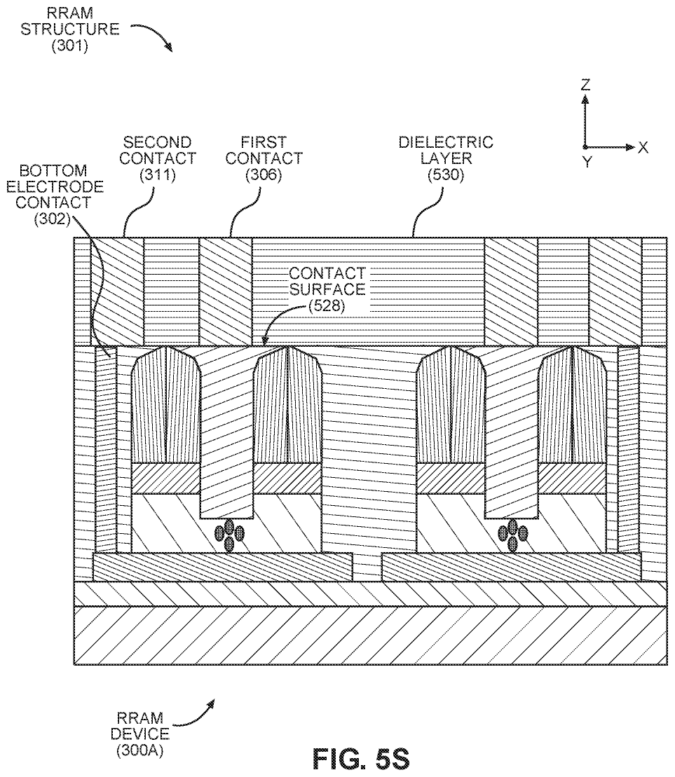

FIG. 4 is a flowchart illustrating an exemplary process 400 of fabricating an RRAM device, such as the RRAM device 300A or 300B in FIG. 3, which includes a bounded region in which the oxide layer is thinner, and an ion concentration is higher, than in a peripheral region surrounding the bounded region to reduce area without increasing performance variability. The process 400 is described below with reference to the exemplary fabrication stages illustrated in FIGS. 5A-5S.

FIG. 5A illustrates an exemplary fabrication stage 500(A) for fabricating the RRAM structure 301, including forming a silicon dioxide (SiO2) layer 504 on a substrate 502 to provide a structural base for the RRAM structure 301. In the example in FIG. 5A, a SiO2 layer 504 is deposited to a thickness in the range of approximately two (2) nanometers (nm) to 10 nm. FIG. 5B illustrates an exemplary fabrication stage 500(B) for fabricating the RRAM structure 301, including forming the bottom electrode 304 on the SiO2 layer 504 (FIG. 4, block 402). In the example in FIG. 5B, the bottom electrode 304 may be formed by depositing a layer of titanium nitride (TiN), tantalum nitride (TaN), or titanium tungsten nitride (TiWN), for example, to a thickness in the range of one (1) nm to ten (10) nm or more. Forming the bottom electrode 304 may include forming a planar top surface S_{304T} on the bottom electrode 304.

FIG. 5C illustrates an exemplary fabrication stage 500(C) for fabricating the RRAM structure 301, including forming the oxide layer 312 having a second thickness T2 above the bottom electrode 304 (shown in FIG. 3). The oxide layer 312 includes a bounded region 313B and a peripheral region 313P surrounding the bounded region 313B (FIG. 4, block 404). The bounded region 313B and the peripheral region 313P, referred to here and with respect to subsequent fabrication stages below, are not shown here, but are clearly shown in the illustration of the completed RRAM structure 301 in FIG. 3, and are also shown in Figures illustrating the subsequent fabrication stages in which those regions are formed (see, for example, FIGS. 5N-5Q). Forming the oxide layer 312 may include depositing a layer of hafnium oxide (HfOx), titanium oxide (TiOx), or a stacked oxide, for example, with “x” in these examples being in a range from 0.5 to 3.5. Forming the oxide layer 312 may including depositing the oxide layer 312 to the second thickness T2 in the range of two (2) nm to twenty (20) nm above the planar top surface S_{304T} of the bottom electrode 304.

FIG. 5D illustrates an exemplary fabrication stage 500(D) for fabricating the RRAM structure 301, including forming the first electrode structure 314-1 of the top electrode 308 on the bounded region 313B and on the peripheral region 313P (shown in FIG. 3) of the oxide layer 312 surrounding the bounded region 313B (FIG. 4, block 406). In the example in FIG. 5D, the first electrode structure 314-1 may be formed by depositing TiN or TaN on the oxide layer 312 to a thickness in the range of one (1) nm to ten (10) nm, or more.

FIG. 5E illustrates an exemplary fabrication stage 500(E) for fabricating the RRAM structure 301, including depositing a polysilicon (poly-Si) layer 508 having a thickness, for example, of about one hundred (100) nm on the first electrode structure 314-1.

FIG. 5F illustrates an exemplary fabrication stage 500(F) for fabricating the RRAM structure 301, employing photo-lithography and etching, for example, to pattern the poly-Si layer 508 of FIG. 5E to form a poly-Si structure 510 over a region in which the bounded region 313B (not shown) of the oxide layer 312 will be formed.

FIG. 5G illustrates an exemplary fabrication stage 500(G) for fabricating the RRAM structure 301, including forming a spacer 316 on the first electrode structure 314-1 above the peripheral region 313P of the oxide layer 312 surrounding the bounded region 313B (FIG. 4, block 408). Forming the spacer 316 in the example in FIG. 5G includes forming the closed outer wall 318-2 around the side surfaces S_{POLY} of the poly-Si structure 510 on the first electrode structure 314-1. Forming a closed outer wall means forming the outer wall 318-2 around the entire perimeter of the poly-Si structure 510 such that the outer wall 318-2 is unbroken all the way around the side surfaces S_{POLY} of the poly-Si structure 510. The outer wall 318-2 may be formed, for example, by depositing a conformal layer (not shown) of SiO2, silicon nitride (SiN), or another compatible material to a thickness in the range of ten (10) nm to twenty (20) nm, and removing the conformal layer from top surfaces of the poly-Si structure 510 and the top electrode 308 by, for example, anisotropic etching. The remaining outer wall 318-2 on the side surfaces S_{POLY} of the poly-Si structure 510 may have a width W_{O} from an inner surface S_{IO} of the outer wall 318-2 to an outer surface S_{OO} of the outer wall 318-2 of ten (10) nm, or in a range from seven (7) nm to thirteen (13) nm. As shown in FIG. 5G, the outer wall 318-2 covers a portion of the oxide layer 312 that will be formed into the peripheral region 313P. The poly-Si structure 510 covers the bounded region 313B of the oxide layer 312 and overlaps onto a portion of the peripheral region 313P having a width W_{I} that is not covered by the outer wall 318-2.

FIG. 5H illustrates an exemplary fabrication stage 500(H) for fabricating the RRAM structure 301, including removing the first electrode structure 314-1 and the oxide layer 312 outside the closed outer wall 318-2 to expose the top surface S_{304T} of the bottom electrode 304 around the outer wall 318-2, including a contact area 512 of the top surface S_{304T} of the bottom electrode 304. In the example in FIG. 5H, portions of the first electrode structure 314-1 and the oxide layer 312 may be removed to expose the top surface S_{304T} of the bottom electrode 304 all the way around the outer wall 318-2, including the contact area 512 of the bottom electrode 304. The first electrode structure 314-1 and the oxide layer 312 may be removed by etching until the top surface S_{304T} of the bottom electrode 304 is exposed.

FIG. 5I illustrates an exemplary fabrication stage 500(I) for fabricating the RRAM structure 301, including removing portions of the bottom electrode 304 outside an area 514 including the oxide layer 312 and the contact area 512 of the bottom electrode 304. As a result, as shown in the example in FIG. 5I, the bottom electrode 304 of the RRAM structure 301 extends outside the outer wall 318-2 to include the contact area 512, but the RRAM structure 301 is otherwise electrically isolated on the SiO2 layer 504.

FIG. 5J illustrates an exemplary fabrication stage 500(J) for fabricating the RRAM structure 301, including depositing a dielectric material 320 over the RRAM structure 301 to a depth higher than the poly-Si structure 510 and removing the dielectric material 320 to expose the poly-Si structure 510. The dielectric material 320 in the example in FIG. 5J may be one of SiO2, SiN, or another dielectric material. The dielectric material 320 may be deposited to a depth of about two hundred (200) nm, for example, to cover the poly-Si structure 510 in the RRAM structure 301. Above the poly-Si structure 510, the dielectric material 320 may be removed by chemical mechanical planarization (CMP) to expose a top surface S_{PS} of the poly-Si structure 510.

FIG. 5K illustrates an exemplary fabrication stage 500(K) for fabricating the RRAM structure 301, including employing photolithography and etching to provide an opening (e.g., contact window) 518 through the entire depth of the dielectric material 320 to expose the contact area 512 of the bottom electrode 304.

FIG. 5L illustrates an exemplary fabrication stage 500(L) for fabricating the RRAM structure 301, including forming a bottom electrode contact 302 on the contact area 512 of the bottom electrode 304. Forming the bottom electrode contact 302 includes filling the opening 518 with a conductive material. In the example in FIG. 5L, the bottom electrode contact 302 may be formed by depositing metal in the opening 518. Forming the bottom electrode contact 302 may also include planarizing the bottom electrode contact 302 to correspond to a top surface S_{PS} of the poly-Si structure 510.

FIG. 5M illustrates an exemplary fabrication stage 500(M) for fabricating the RRAM structure 301, including removing the poly-Si structure 510 in FIG. 5L. In the example in FIG. 5M, selective etching is employed to remove the poly-Si material of the poly-Si structure 510, stopping on the first electrode structure 314-1. Removing the poly-Si structure 510 exposes the first electrode structure 314-1 and the inner surface S_{IO} of the outer wall 318-2.

FIG. 5N illustrates an exemplary fabrication stage 500(N) for fabricating the RRAM structure 301, including forming the inner wall 318-1 having the width W_{I} inside the outer wall 318-2 on the first electrode structure 314-1 above the portion of the peripheral region 313P having the width W_{I}, which was previously overlapped by the poly-Si structure 510 (not shown here). In the example in FIG. 5N, forming the inner wall 318-1 may include depositing a SiO2 or SiN material on the inner surface S_{IO} of the outer wall 318-2 to a thickness in the range of five (5) nm to twenty (20) nm. As in the formation of the outer wall 318-2, the SiO₂ or SiN material may be deposited in a conformal layer that is etched in an anisotropic process to remain only on the inner surface S_{IO} of the outer wall 318-2. The resulting inner wall 318-1 is a closed wall having a width W_{I} in the range of one (1) nm to ten (10) nm between an inner surface S_{II} and an outer surface S_{OI} of the inner wall 318-1. FIG. 5N illustrates a fabrication stage at which a portion 520 of the first electrode structure 314-1 has already been removed. Prior to removal, the portion 520 is exposed inside the closed inner wall 318-1. The portion 520 is bounded by the inner surface S_{II} of the inner wall 318-1, and the portion 520 corresponds to the bounded region 313B of the oxide layer 312. In this regard, the portion 520 is not shown in FIG. 5N because the fabrication stage 500(N) further includes removing the portion 520 of the first electrode structure 314-1 of the top electrode 308 above the bounded region 313B of the oxide layer 312 (FIG. 4, block 410). The portion 520 is removed by selectively etching the TiN or TaN, of which the first electrode structure 314-1 of the top electrode 308 is formed, inside the inner wall 318-1. The area of the oxide layer 312 beneath the removed portion 520 of the first electrode structure 314-1 is the bounded region 313B of the oxide layer 312. In other words, the boundary of the bounded region 313B is determined by the inner surface S_{II} of the inner wall 318-1. The remaining first electrode structure 314-1 and the inner surface S_{II} of the inner wall 318-1 provide an opening 522 to the bounded region 313B of the oxide layer 312.

FIG. 5O illustrates an exemplary fabrication stage 500(O) for fabricating the RRAM structure 301, including implanting mobile ions in the bounded region 313B of the oxide layer 312 to intentionally create defects 310 in the bounded region 313B of the oxide layer 312. In the example in FIG. 5O, the ions are provided through the opening 522 formed by the inner wall 318-1 and the first electrode structure 314-1 and implanted into the bounded region 313B. In this process, ions are not implanted in the peripheral region 313P, which is covered by the spacer 316 including the inner wall 318-1 and the outer wall 318-2. Thus, the width W_{P} of the peripheral region 313P is equal to the width W_{I} of the inner wall 318-1 plus the width W_{O} of the outer wall 318-2. The defects 310 in the example may be created by implanted oxygen ions or other species of ions including Hf, Ti, Ta, or Mn, for example. In one aspect, the mobile ions may be implanted with implantation energy in the range of 5 KeV to 200 KeV and a dose resulting in a mobile ion concentration of 10E11/cm² to 10E14/cm² in the bounded region 313B. In another aspect, the mobile ion concentration in the bounded region 313B is controlled, for example, to be at least twice the concentration of mobile ions implanted in the peripheral region 313P.

FIG. 5P illustrates an exemplary fabrication stage 500(P) for fabricating the RRAM structure 301, including thinning the bounded region 313B of the oxide layer 312 to the first thickness T1 that may be in the range of one (1) nm to (5) nm thinner than the second thickness T2 (FIG. 4, block 412). Thinning the bounded region 313B may further comprise etching a top surface of the oxide layer 312 where the portion 520 of the first electrode structure 314-1 was removed. Etching the oxide layer 312 may employ either a dry etch process or a wet etch process. The first thickness T1 of the oxide layer 312 in the bounded region 313B may be less than the second thickness T2 in the peripheral region 313P by a range of one (1) nm to ten (10) nm. In this regard, the first thickness T1 of the oxide layer 312 in the bounded region 313B may be in the range of 50% to 90% of the second thickness T2 in the peripheral region 313P

FIG. 5Q illustrates an exemplary fabrication stage 500(Q) for fabricating the RRAM structure 301, including forming the second electrode structure 314-2 of the top electrode 308 on the bounded region 313B of the oxide layer 312, extending above the first electrode structure 314-1 of the top electrode 308 and surrounded by the spacer 316 (FIG. 4, block 414). In particular, forming the second electrode structure 314-2 of the top electrode 308 includes disposing the second electrode structure 314-2 through the first electrode structure 314-1 where the portion 520 of the first electrode structure 314-1 was removed. As noted above, the spacer 316 includes the outer wall 318-2 and the inner wall 318-1 formed on the first electrode structure 314-1 over the peripheral region 313P of the oxide layer 312. Forming the second electrode structure 314-2 includes depositing electrode material 526 through the opening 522 in the inner wall 318-1 and onto the bounded region 313B, such that the electrode material 526 extends above the first electrode structure 314-1 of the top electrode 308 and is surrounded by the inner wall 318-1. The electrode material 526 includes conductive materials, such as TiN, TaN, TiWN, tungsten (W), etc. Excess electrode material 526 above the spacer 316 and on the top surface 517 of the dielectric material 320 may be removed by CMP, for example, to provide a contact surface 528 of the top electrode 308. By the deposition process in fabrication stage 500(Q), the second electrode structure 314-2 of the top electrode 308 is in direct contact with and electrically coupled to the first electrode structure 314-1 of the top electrode 308.

Thus, a voltage applied to the contact surface 528 of the top electrode 308 is also supplied in the bounded region 313B of the oxide layer 312 by the second electrode structure 314-2 and in the peripheral region 313P of the oxide layer 312 by the first electrode structure 314-1. A voltage differential between the bottom electrode 304 and the top electrode 308 will create an electric field in the oxide layer 312. Since the oxide layer 312 is thinner in the bounded region 313B than in the peripheral region 313P, an electric field strength in the bounded region 313B is greater than an electric field strength in the peripheral region 313P. In addition, with ions implanted in the bounded region 313B in fabrication stage 500(O), there is a higher concentration of defects 310 created in the oxide layer 312 in the bounded region 313B than in the peripheral region 313P. The thinner oxide layer 312 and higher concentration of defects 310 in the bounded region 313B improves the conditions for filament formation, which increases a probability that filaments will be limited to the bounded region 313B and reduces variability of filament formation. The outer wall 318-2 reduces edge effects of the bounded region 313B, which contributes to more uniform behavior in the bounded region 313B. However, with filament formation essentially limited to the bounded region 313B, the width W_{P} of the peripheral region 313P can be reduced without reducing reliability of an RRAM device. Since the width W_{P} of the peripheral region 313P corresponds to the width W_{I} of the inner wall 318-1 and the width W_{O} of the outer wall 318-2, the size of the spacer 316 and, therefore, the size of the RRAM device 300A can be adjusted by changing the widths W_{I} and W_{O}.

FIG. 5R illustrates an exemplary fabrication stage 500(R) for fabricating the RRAM structure 301, including depositing a dielectric layer 530 on the RRAM structure 301 over the contact surface 528, the dielectric material 320, and the bottom electrode contact 302.

FIG. 5S illustrates an exemplary fabrication stage 500(S) for fabricating the RRAM structure 301, including employing photolithography and etching to remove the dielectric layer 530 above the bottom electrode contact 302 and the contact surface 528 of the top electrode 308 and filling the openings to create a bottom contact 532 and a top contact 534 for supplying a voltage differential to the RRAM device 300A.

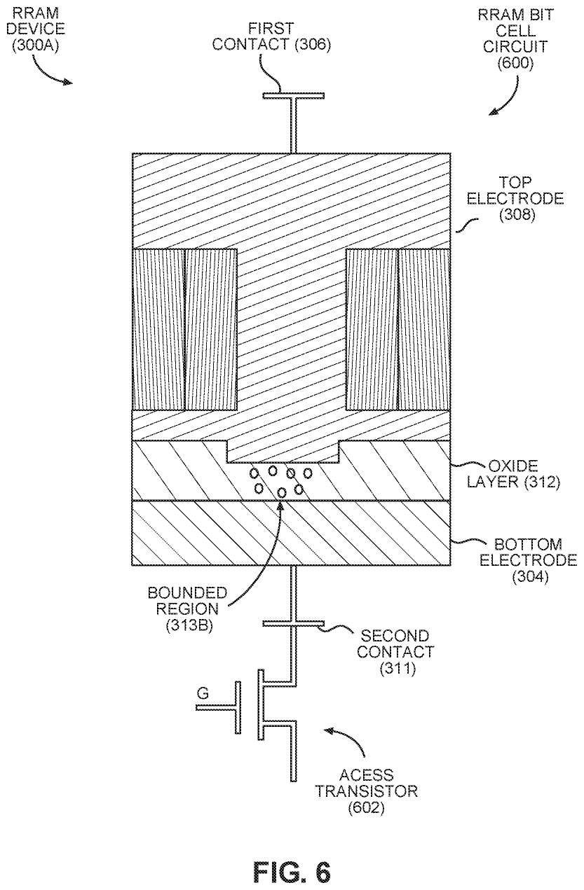

FIG. 6 is a schematic diagram of an RRAM bit cell circuit 600 that employs the RRAM device 300A in FIG. 3 for storing a memory state and an access transistor 602 to control a read or write operation by controlling supply of a voltage to the bottom electrode 304. An external circuit (not shown) may supply a gate voltage V_{DD} to the gate G of the access transistor 602 to turn on the access transistor 602 for a storage operation comprising either a read operation or a write operation. In a write operation of the RRAM bit cell circuit 600, the access transistor 602 is configured to supply a bit line voltage to the bottom electrode 304 of the RRAM device 300A in response to the gate voltage V_{DD}. Based on a voltage differential between the bit line voltage and a voltage applied to the top electrode 308 of the RRAM device 300A, a first voltage V_{SET} or a second voltage V_{RESET} is applied between the bottom electrode 304 and the top electrode 308 to store a data value as a resistance state (e.g., LRS or HRS). A first voltage V_{SET} applied between the bottom electrode 304 and the top electrode 308 of the RRAM device 300A will create a filament in the bounded region 313B of the oxide layer 312 to set the RRAM device 300A in a low-resistance state (LRS). A second voltage V_{RESET} applied between the bottom electrode 304 and the top electrode 308 will disperse a filament existing in the bounded region 313B to reset the RRAM device 300A to a high-resistance state (HRS). In a read operation, a sensing voltage V_{SENSE} applied between the bottom electrode 304 and the top electrode 308 of the RRAM device 300A will not set or reset the state of the RRAM device 300A, but will cause a current to pass through the RRAM device 300A to allow an external circuit (not shown) to sense whether the RRAM device 300A is set in the LRS or reset in the HRS.

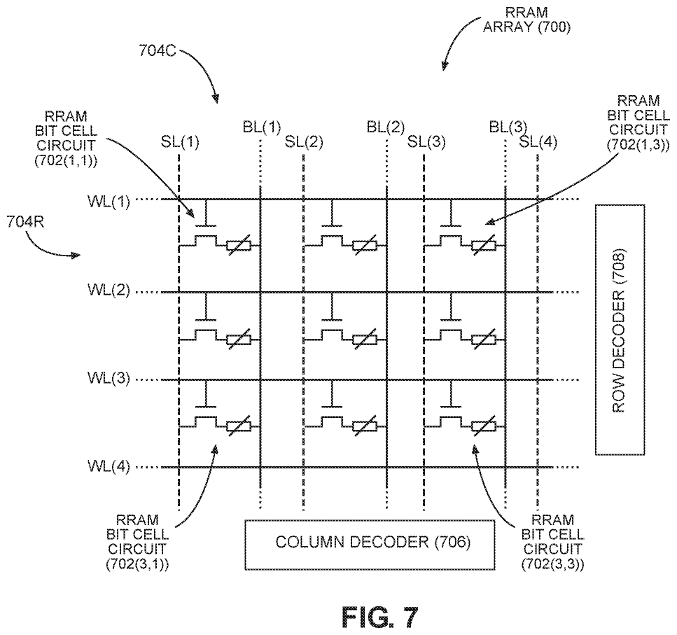

FIG. 7 is a schematic diagram of an exemplary RRAM array 700 comprising a plurality of RRAM bit cell circuits 702(1,1)-702(M,N) organized in rows and columns. The RRAM bit cell circuits 702(1,1)-702(M,N) may each comprise the RRAM bit cell circuit 600 in FIG. 6 including the RRAM device 300A in FIG. 3. RRAM bit cell circuits 702(1,1)-702(1,3) of a first row 704R, and RRAM bit cell circuits 702(1,1)-702(3,1) of a first column 704C are shown, but the RRAM array 700 may have M rows and N columns including M×N RRAM bit cell circuits 702(M,N), where M and N may be any integer, such as 32, 512, 2048, etc. The RRAM array 700 includes access circuitry for accessing the RRAM bit cell circuits 702(1,1)-702(M,N) including a column decoder 706 configured to provide the word line voltage V_{WL} on word lines WL(1)-WL(M) and a row decoder 708 configured to provide the source line voltage V_{SL} on source lines SL(1)-SL(N) and bit line voltage V_{BL} on bit lines BL(1)-BL(N) to read or write data in at least one of the plurality of RRAM bit cell circuits 702(1,1)-702(M,N), as described above. Each of the RRAM bit cell circuits 702(1,1)-702(M,N) includes the RRAM bit cell circuit 600 of FIG. 6 employing the RRAM device 300A of FIG. 3. Each RRAM device 300A of the RRAM array 700 includes a bottom electrode 304, an oxide layer 312 disposed over the bottom electrode 304, a top electrode 308, and a spacer 316. The oxide layer 312 includes a bounded region 313B having a first thickness T1 and a peripheral region 313P surrounding the bounded region 313B and having a second thickness T2 greater than the first thickness T1. The top electrode 308 in the RRAM array 700 is configured to receive a bit line voltage V_{BL} on a bit line BL, and the top electrode 308 includes a first electrode structure 314-1 disposed on the oxide layer 312 in the peripheral region 313P and a second electrode structure 314-1 extending below the first electrode structure 314-1 and disposed on the oxide layer 312 in the bounded region 313B. The spacer 316 is disposed around the second electrode structure 314-2 of the top electrode 308 and above the first electrode structure 314-1 of the top electrode 308. The RRAM bit cell circuit 600 also includes an access transistor 602 configured to couple a first source line voltage V_{SL} to the bottom electrode 304 of the RRAM device 300 in response to a gate voltage V_{GL} received on a word line WL. The oxide layer 312 in the RRAM device 300A in the RRAM array 700 is configured to reversibly switch between the LRS and the HRS in response to a first voltage differential between the top electrode 308 and the bottom electrode 304. The RRAM array 700 may further include access circuitry, including the column decoder 706 and the row decoder 708, configured to supply the gate voltage V_{GL} on the word line WL, supply the bit line voltage V_{BL} on the bit line BL, and supply the source line voltage V_{SL} on the source line SL in a memory write operation. The access circuitry, including the column decoder 706 and the row decoder 708, is further configured to supply the bit line voltage V_{BL} on the bit line BL and supply a second source line voltage V_{SL} to provide a second voltage differential between the top electrode 308 and the bottom electrode 304 in a memory read operation. An RRAM array 700 of a plurality of RRAM bit cell circuits 600 each employing the RRAM device 300A in FIG. 3 may have a reduced area compared to a conventional RRAM array.

RRAM bit cell circuits including an RRAM device with a bounded filament formation region in which the oxide layer is thinner and the ion concentration is higher than in a peripheral region of the oxide layer to allow scaling without decreasing reliability, as illustrated in any of FIGS. 2A, 3, and 5S, and according to any aspects disclosed herein, may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

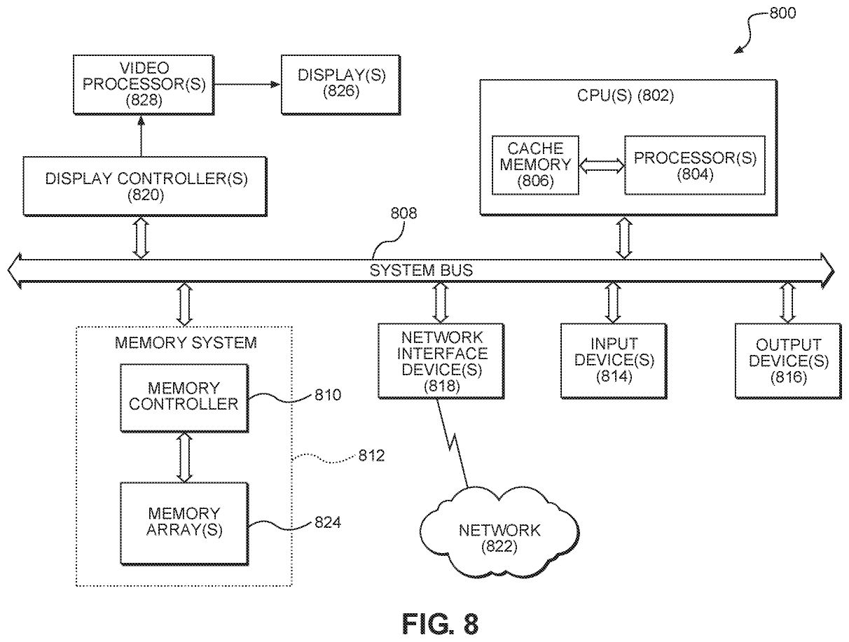

In this regard, FIG. 8 illustrates an example of a processor-based system 800 that can include the RRAM bit cell circuit 600 of FIG. 6 including the RRAM device 200, 300A, or 300B of FIG. 2A, 3, or 5S that includes a bounded region in which the oxide layer is thinner and the ion concentration is higher than in a peripheral region of the oxide layer to allow scaling without decreasing reliability and according to any aspects disclosed herein. In this example, the processor-based system 800 includes one or more central processor units (CPUs) 802, which may also be referred to as CPU or processor cores, each including one or more processors 804. The CPU(s) 802 may have cache memory 806 coupled to the processor(s) 804 for rapid access to temporarily stored data. As an example, the CPUs 610 could include the RRAM bit cell circuit 600 of FIG. 6 including the RRAM device 200, 300A, or 300B of FIG. 2A, 3 or 5S that includes a bounded region in which the oxide layer is thinner and the ion concentration is higher than in a peripheral region of the oxide layer to allow scaling without decreasing reliability and according to any aspects disclosed herein. The CPU(s) 802 is coupled to a system bus 808 and can intercouple master and slave devices included in the processor-based system 800. As is well known, the CPU(s) 802 communicates with these other devices by exchanging address, control, and data information over the system bus 808. For example, the CPU(s) 802 can communicate bus transaction requests to a memory controller 810 as an example of a slave device. Although not illustrated in FIG. 8, multiple system buses 808 could be provided, wherein each system bus 808 constitutes a different fabric.

Other master and slave devices can be connected to the system bus 808. As illustrated in FIG. 8, these devices can include a memory system 812 that includes the memory controller 810, one or more input devices 814, one or more output devices 816, one or more network interface devices 818, and one or more display controllers 820, as examples. Each of the memory system 812, the one or more input devices 814, the one or more output devices 816, the one or more network interface devices 818, and the one or more display controllers 820 can include the RRAM bit cell circuit 600 of FIG. 6 including the RRAM device 200, 300A, or 300B of FIG. 2A, 3, or 5S that includes a bounded region in which the oxide layer is thinner and the ion concentration is higher than in a peripheral region of the oxide layer to allow scaling without decreasing reliability and according to any aspects disclosed herein. The input device(s) 814 can include any type of input device, including, but not limited to, input keys, switches, voice processors, etc. The output device(s) 816 can include any type of output device, including, but not limited to, audio, video, other visual indicators, etc. The network interface device(s) 818 can be any device configured to allow exchange of data to and from a network 822. The network 822 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 818 can be configured to support any type of communications protocol desired. The memory system 812 can include one or more memory arrays 824.

The CPU(s) 802 may also be configured to access the display controller(s) 820 over the system bus 808 to control information sent to one or more displays 826. The display controller(s) 820 sends information to the display(s) 826 to be displayed via one or more video processors 828, which process the information to be displayed into a format suitable for the display(s) 826. The display(s) 826 can include any type of display, including, but not limited to, a cathode ray tube (CRT), a liquid crystal display (LCD), a plasma display, a light emitting diode (LED) display, etc. The display controller(s) 820, display(s) 826, and/or the video processor(s) 828 can include the RRAM bit cell circuit 600 of FIG. 6 including the RRAM device 200, 300A, or 300B of FIG. 2A, 3, or 5S that includes a bounded region in which the oxide layer is thinner and the ion concentration is higher than in a peripheral region of the oxide layer to allow scaling without decreasing reliability and according to any aspects disclosed herein.

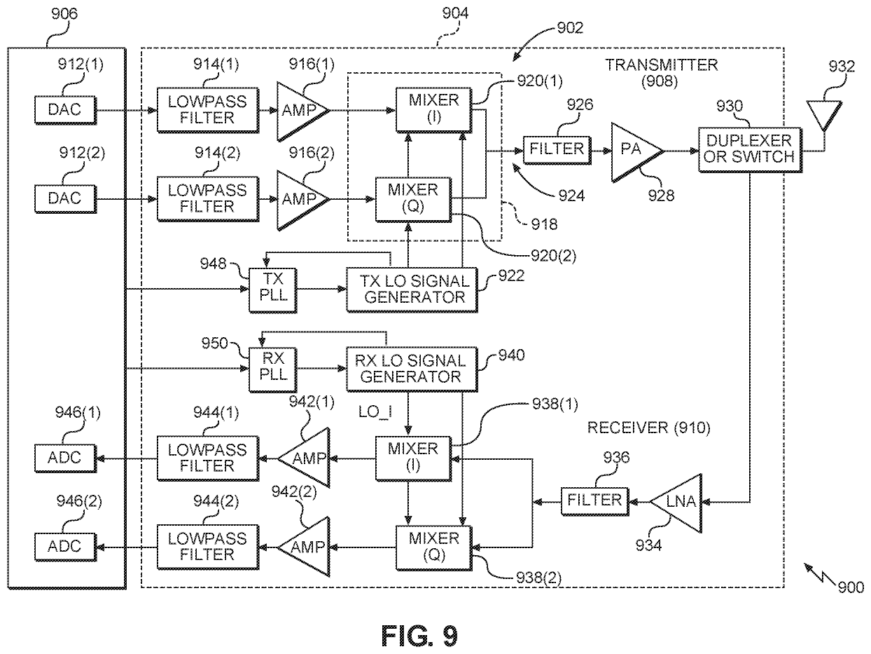

FIG. 9 illustrates an exemplary wireless communications device 900 that includes radio frequency (RF) components formed from an IC 902, wherein any of the components therein can include the RRAM bit cell circuit 600 of FIG. 6 including the RRAM device 200, 300A, or 300B of FIG. 2A, 3, or 5S that includes a bounded region in which the oxide layer is thinner and the ion concentration is higher than in a peripheral region of the oxide layer to allow scaling without decreasing reliability and according to any aspects disclosed herein. The wireless communications device 900 may include or be provided in any of the above-referenced devices, as examples. As shown in FIG. 9, the wireless communications device 900 includes a transceiver 904 and a data processor 906. The data processor 906 may include a memory to store data and program codes. The transceiver 904 includes a transmitter 908 and a receiver 910 that support bi-directional communications. In general, the wireless communications device 900 may include any number of transmitters 908 and/or receivers 910 for any number of communication systems and frequency bands. All or a portion of the transceiver 904 may be implemented on one or more analog ICs, RF ICs (RFICs), mixed-signal ICs, etc.

The transmitter 908 or the receiver 910 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage, and then from IF to baseband in another stage for the receiver 910. In the direct-conversion architecture, a signal is frequency-converted between RF and baseband in one stage. The super-heterodyne and direct-conversion architectures may use different circuit blocks and/or have different requirements. In the wireless communications device 900 in FIG. 9, the transmitter 908 and the receiver 910 are implemented with the direct-conversion architecture.

In the transmit path, the data processor 906 processes data to be transmitted and provides I and Q analog output signals to the transmitter 908. In the exemplary wireless communications device 900, the data processor 906 includes digital-to-analog converters (DACs) 912(1), 912(2) for converting digital signals generated by the data processor 906 into the I and Q analog output signals, e.g., I and Q output currents, for further processing.

Within the transmitter 908, lowpass filters 914(1), 914(2) filter the I and Q analog output signals, respectively, to remove undesired signals caused by the prior digital-to-analog conversion. Amplifiers (AMPs) 916(1), 916(2) amplify the signals from the lowpass filters 914(1), 914(2), respectively, and provide I and Q baseband signals. An upconverter 918 upconverts the I and Q baseband signals with I and Q transmit (TX) local oscillator (LO) signals through mixers 920(1), 920(2) from a TX LO signal generator 922 to provide an upconverted signal 924. A filter 926 filters the upconverted signal 924 to remove undesired signals caused by the frequency upconversion as well as noise in a receive frequency band. A power amplifier (PA) 928 amplifies the upconverted signal 924 from the filter 926 to obtain the desired output power level and provides a transmitted RF signal. The transmitted RF signal is routed through a duplexer or switch 930 and transmitted via an antenna 932.

In the receive path, the antenna 932 receives signals transmitted by base stations and provides a received RF signal, which is routed through the duplexer or switch 930 and provided to a low noise amplifier (LNA) 934. The duplexer or switch 930 is designed to operate with a specific receive (RX)-to-TX duplexer frequency separation, such that RX signals are isolated from TX signals. The received RF signal is amplified by the LNA 934 and filtered by a filter 936 to obtain a desired RF input signal. Downconversion mixers 938(1), 938(2) mix the output of the filter 936 with I and Q RX LO signals (i.e., LO_I and LO_Q) from an RX LO signal generator 940 to generate I and Q baseband signals. The I and Q baseband signals are amplified by amplifiers (AMPs) 942(1), 942(2) and further filtered by lowpass filters 944(1), 944(2) to obtain I and Q analog input signals, which are provided to the data processor 906. In this example, the data processor 906 includes analog-to-digital converters (ADCs) 946(1), 946(2) for converting the analog input signals into digital signals to be further processed by the data processor 906.

In the wireless communications device 900 of FIG. 9, the TX LO signal generator 922 generates the I and Q TX LO signals used for frequency upconversion, while the RX LO signal generator 940 generates the I and Q RX LO signals used for frequency downconversion. Each LO signal is a periodic signal with a particular fundamental frequency. A TX phase-locked loop (PLL) circuit 948 receives timing information from the data processor 906 and generates a control signal used to adjust the frequency and/or phase of the TX LO signals from the TX LO signal generator 922. Similarly, an RX PLL circuit 950 receives timing information from the data processor 906 and generates a control signal used to adjust the frequency and/or phase of the RX LO signals from the RX LO signal generator 940.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. The master and slave devices described herein may be employed in any circuit, hardware component, IC, or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but, is to be accorded the widest scope consistent with the principles and novel features disclosed herein.

1. A resistive random access memory (RRAM) device, comprising:
a bottom electrode comprising a top surface;
an oxide layer disposed on the top surface of the bottom electrode, the oxide layer comprising:
a bounded region having a first thickness above the top surface of the bottom electrode; and
a peripheral region surrounding the bounded region and having a second thickness above the top surface of the bottom electrode greater than the first thickness;
a top electrode comprising:
a first electrode structure disposed on the oxide layer in the peripheral region; and
a second electrode structure disposed on the oxide layer in the bounded region and above the first electrode structure over the bounded region; and
a spacer disposed around the second electrode structure of the top electrode and above the first electrode structure of the top electrode.

2. The RRAM device of claim 1, wherein the top surface of the bottom electrode comprises a planar top surface and the oxide layer is disposed on the planar top surface.

3. The RRAM device of claim 1, wherein the bounded region of the oxide layer comprises a defect concentration due to implanted mobile ions that is at least twice a defect concentration in the peripheral region of the oxide layer.

4. The RRAM device of claim 3, wherein the defect concentration due to the implanted mobile ions in the bounded region of the oxide layer is in the range of 10E11/cm² to 10E14/cm².

5. The RRAM device of claim 3, wherein a depth of the implanted mobile ions in the bounded region of the oxide layer is based on implantation energy in the range of 5 Kilo electron Volts (KeV) to 200 KeV.

6. The RRAM device of claim 1, wherein the first thickness of the bounded region of the oxide layer is in a range of 50% to 90% of the second thickness of the peripheral region of the oxide layer.

7. The RRAM device of claim 1, wherein the first thickness of the bounded region of the oxide layer is in a range of one nanometer (1 nm) to ten (10) nm less than the second thickness of the peripheral region of the oxide layer.

8. The RRAM device of claim 1, wherein the peripheral region provides a continuous boundary around an entire perimeter of the bounded region.

9. The RRAM device of claim 1, wherein the second electrode structure of the top electrode is electrically coupled to the first electrode structure of the top electrode.

10. The RRAM device of claim 1, wherein an axis of the second electrode structure of the top electrode extends along an axis in a direction orthogonal to a plane of the first electrode structure of the top electrode.

11. The RRAM device of claim 1, further comprising a contact coupled to the top electrode formed on the second electrode structure.

12. The RRAM device of claim 1, wherein the spacer comprises an inner wall disposed around the second electrode structure of the top electrode and an outer wall disposed around the inner wall.

13. The RRAM device of claim 1, further comprising a bottom electrode contact formed on the top surface of the bottom electrode.

14. The RRAM device of claim 1 integrated in an integrated circuit (IC).

15. The RRAM device of claim 1, integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

16. A method of fabricating a resistive random access memory (RRAM) device, comprising:
forming a bottom electrode;
forming an oxide layer having a second thickness above the bottom electrode, the oxide layer comprising a bounded region and a peripheral region surrounding the bounded region;
forming a first electrode structure of a top electrode on the bounded region of the oxide layer and on the peripheral region of the oxide layer surrounding the bounded region;
forming a spacer on the first electrode structure above the peripheral region of the oxide layer surrounding the bounded region;
removing a portion of the first electrode structure of the top electrode above the bounded region of the oxide layer;
thinning the bounded region of the oxide layer to a first thickness; and
forming a second electrode structure of the top electrode on the bounded region of the oxide layer extending above the first electrode structure of the top electrode and surrounded by the spacer.

17. The method of claim 16, wherein:
forming the bottom electrode further comprises forming a planar top surface on the bottom electrode; and
forming the oxide layer further comprises forming the oxide layer on the planar top surface of the bottom electrode.

18. The method of claim 16, wherein forming the spacer further comprises:
forming a poly-silicon (poly-Si) structure over the bounded region and overlapping a portion of the peripheral region of the oxide layer; and
forming a closed outer wall around the poly-Si structure on the top electrode.

19. The method of claim 18, further comprising:
removing the poly-Si structure; and
forming a closed inner wall of the spacer inside the closed outer wall on the top electrode above the portion of the peripheral region of the oxide layer overlapped by the poly-Si structure.

20. The method of claim 18, further comprising:
removing the first electrode structure of the top electrode and the oxide layer outside the closed outer wall of the spacer to expose a contact area of the bottom electrode.

21. The method of claim 20, further comprising:
forming a bottom electrode contact on the contact area of the bottom electrode.

22. The method of claim 16, further comprising:
implanting ions in the bounded region of the oxide layer.

23. The method of claim 16, wherein thinning the oxide layer further comprises:
etching a top surface of the oxide layer where the portion of the first electrode structure of the top electrode is removed.

24. The method of claim 16 wherein:
forming the second electrode structure of the top electrode further comprises disposing the second electrode structure through the first electrode structure where the portion of the first electrode structure is removed.

25. A memory array comprising one or more resistive random access memory (RRAM) bit cell circuits each comprising:
a resistive random access memory (RRAM) device, comprising:
a bottom electrode;
an oxide layer disposed over the bottom electrode, the oxide layer comprising:
a bounded region having a second thickness; and
a peripheral region surrounding the bounded region and having a first thickness greater than the second thickness; and
a top electrode configured to receive a bit line voltage on a bit line, the top electrode comprising:
a first electrode structure disposed on the oxide layer in the peripheral region; and
a second electrode structure extending below the first electrode structure and disposed on the oxide layer in the bounded region; and
a spacer disposed around the second electrode structure of the top electrode and above the first electrode structure of the top electrode; and
an access transistor configured to couple a first source line voltage to the bottom electrode of the RRAM device in response to a gate voltage received on a word line;
wherein the oxide layer is configured to reversibly switch between a low-resistance state (LRS) and a high-resistance state (HRS) in response to a first voltage differential between the top electrode and the bottom electrode.

26. The memory array of claim 25, further comprising:
access circuitry configured to supply the gate voltage on the word line, supply the bit line voltage on the bit line, and supply the source line voltage on the source line in a memory write operation.

27. The memory array of claim 26, wherein:
the access circuitry is further configured to supply the bit line voltage on the bit line and supply a second source line voltage to provide a second voltage differential between the top electrode and the bottom electrode in a memory read operation.
